(19) United States
(12) Patent Application Publication
(10) Pub. No.: US 2015/0060799 A1
(43) Pub. Date: Mar. 5, 2015

(54) ORGANIC ELECTROLUMINESCENT ELEMENT

(71) Applicant: PANASONIC CORPORATION, Osaka (JP)

(72) Inventors: Hirofumi Kubota, Osaka (JP); Yuko Suzuka, Osaka (JP)

(21) Appl. No.: 14/381,684

(22) PCT Filed: Feb. 25, 2013
(86) PCT No.: PCT/JP2013/001062

§ 371 Date: Aug. 28, 2014

(30) Foreign Application Priority Data
Mar. 13, 2012 (JP) 2012-055278

(51) Int. Cl. H01L 51/52

(52) U.S. Cl. CPC H01L 51/5212; H01L 51/5209
USPC 257/40

(57) ABSTRACT

This disclosure relates to an organic electroluminescent element including a light-emitting layer disposed between electrodes. At least one of the electrodes is a transparent electrode that has light transmitting property. An auxiliary electrode formed of a metal is disposed on an opposite side of the transparent electrode from a side of the light-emitting layer. The auxiliary electrode is provided with a plurality of holes. The plurality of holes have at least two kinds of geometrical shapes in plan view.

### TECHNICAL FIELD

The invention relates to an organic electroluminescent element (hereinafter, also referred to as an “organic EL element”) used for an illumination apparatus or the like.

### BACKGROUND ART

Conventionally, a planar organic EL element has been known as an organic electroluminescent panel (also referred to as an “organic EL panel”). In the organic EL panel, as a panel area (substrate area) thereof is more increased, there is a case where a sheet resistance of a transparent electrode, configured by an ITO film (Indium Tin Oxide film) and the like, is also more increased. For this reason, while luminance at a peripheral part near an end of the transparent electrode is increased, luminance at a central part of the transparent electrode is reduced, and accordingly, uniformity of in-plane light emission luminance tends to be reduced. Therefore, various structures have been proposed for enhancing the uniformity of the in-plane light emission luminance (for example, see JP2006-253302A).

For example, in an organic EL panel shown in FIG. 13, a grid-like auxiliary electrode 22 is provided on a surface of a substrate 1 on which an ITO film 21 is formed. The auxiliary electrode 22 is formed of a material, such as a metal, which has conductivity higher than the ITO film 21. In this case, current is easily supplied also to a central part of the ITO film 21 through the auxiliary electrode 22, thereby reducing a current amount difference between the central part and a peripheral part of the ITO film 21. Therefore, it is possible to enhance the uniformity of the in-plane light emission luminance of the organic EL panel.

However, in the above-mentioned organic EL panel, when a view angle is deep, grids of the auxiliary electrode 22 overlap each other. Accordingly, the light emission luminance tends to be reduced. In addition, when an interval between grids is made to be small, there is a problem that diffraction easily occurs and light emission color easily changes. Further, it is hard to uniformize current density of the ITO film 21 even with the grid-like auxiliary electrode 22, and accordingly, there is a problem that it is hard to more enhance the uniformity of the light emission luminance.

### DISCLOSURE OF THE INVENTION

It is an object of the present invention to provide an organic electroluminescent element, which can prevent reduction of light emission luminance even when a view angle is deep, and reduce change of light emission color by preventing occurrence of diffraction due to an auxiliary electrode, and easily uniformize current density of a transparent electrode, and easily enhance uniformity of the light emission luminance.

An organic electroluminescent element according to an aspect of the present invention includes: a light-emitting layer disposed between electrodes; and an auxiliary electrode. At least one of the electrodes is a transparent electrode that has light transmitting property. The auxiliary electrode is disposed on an opposite side of the transparent electrode from a side of the light-emitting layer. The auxiliary electrode is formed of a metal. The auxiliary electrode is provided with a plurality of holes that have at least two kinds of geometrical shapes in plan view.

In this organic electroluminescent element, preferably, the auxiliary electrode includes a grid electrode that is formed into a grid-shape by arranging a plurality of elongated members so as to cross mutually, or so as to be joined mutually by prescribed angles. Preferably, the plurality of holes include a plurality of openings that are formed by being surrounded by the plurality of elongated members.

In this organic electroluminescent element, preferably, the plurality of openings have polygonal shapes in plan view, and corners of each opening have round shapes in plan view. Preferably, an opening among the plurality of openings is disposed on a side of a peripheral part of an emission region of the light-emitting layer, and a curvature radius of a corner of the opening is set to be larger than a curvature radius of a corner of an opening disposed on a side of a central part of the emission region.

In this organic electroluminescent element, preferably, the plurality of holes include a through-hole in addition to the plurality of openings, and the through-hole is formed in a crossing part at which the plurality of elongated members cross mutually.

In this organic electroluminescent element, preferably, the plurality of holes include a through-hole in addition to the plurality of openings, and the through-hole is formed in a joining part at which the plurality of elongated members are joined mutually by the prescribed angles.

In this organic electroluminescent element, preferably, the plurality of holes include at least one hole that has a circle or an ellipse in plan view.

In this organic electroluminescent element, preferably, the plurality of holes include at least one hole that has a polygonal shape in plan view.

In this organic electroluminescent element, preferably, the plurality of holes include a coupling-hole for coupling holes that are mutually adjacent in plan view.

In this organic electroluminescent element, preferably, the plurality of holes are arranged so as to have four-hold rotational symmetry around a rotational axis that is at a center of the emission region of the light-emitting layer.

In this organic electroluminescent element, preferably, the auxiliary electrode has a low-opening-rate region at the peripheral part of the emission region of the light-emitting layer, and, among the plurality of holes, an opening area of holes in the low-opening-rate region is lower than an opening area of holes in a region corresponding to the central part of the emission region.

In this organic electroluminescent element, preferably, the auxiliary electrode has a high-opening-rate region at the peripheral part of the emission region of the light-emitting layer, and, among the plurality of holes, an opening area of holes in the high-opening-rate region is higher than an opening area of holes in a region corresponding to the central part of the emission region.

In this organic electroluminescent element, preferably, the auxiliary electrode is provided at an outer peripheral edge thereof with a power supply terminal for power supply, and, the low-opening-rate region is disposed at a position close to the power supply terminal.

In this organic electroluminescent element, preferably, the auxiliary electrode is provided at an outer peripheral edge thereof with a power supply terminal for power supply, and, the high-opening-rate region is disposed at a position close to the power supply terminal.

In this organic electroluminescent element, preferably, an opening rate of the low-opening-rate region is lower than an opening rate of the region corresponding to the central part by at least 5% or more.

In this organic electroluminescent element, preferably, an opening rate of the high-opening-rate region is higher than an opening rate of the region corresponding to the central part by at least 5% or more.

According to the aspect of the present invention, the auxiliary electrode is provided with the plurality of holes that have at least two kinds of geometrical shapes in plan view. Therefore, it is possible to prevent reduction of light emission luminance even when a view angle is deep, and reduce change of light emission color by preventing occurrence of diffraction due to the auxiliary electrode, and easily uniformize current density of the transparent electrode, and easily enhance uniformity of the light emission luminance.

### BRIEF DESCRIPTION OF THE DRAWINGS

Preferred embodiments of the present invention will now be described in further details. Other features and advantages of the present invention will become better understood with regard to the following detailed description and accompanying drawings where:

FIG. 1 is a cross-section view of one example of an organic EL element according to First Embodiment;

FIG. 2 is a plan view of one example of an auxiliary electrode in the organic EL element according to the First Embodiment;

FIG. 3 is a plan view of another example of the auxiliary electrode in the organic EL element according to the First Embodiment;

FIG. 4 is a plan view of yet another example of the auxiliary electrode in the organic EL element according to the First Embodiment;

FIG. 5 is a plan view of yet another example of the auxiliary electrode in the organic EL element according to the First Embodiment;

FIG. 6 is a plan view of yet another example of the auxiliary electrode in the organic EL element according to the First Embodiment;

FIG. 7 is a plan view of yet another example of the auxiliary electrode in the organic EL element according to the First Embodiment;

FIG. 8 is a plan view of yet another example of the auxiliary electrode in the organic EL element according to the First Embodiment;

FIG. 9 is a plan view of one example of an auxiliary electrode in an organic EL element according to Second Embodiment;

FIG. 10 is an enlarged plan view of a side of a central part in the one example of the auxiliary electrode in the organic EL element according to the Second Embodiment;

FIG. 11 is an enlarged plan view of a side of a peripheral part in the one example of the auxiliary electrode in the organic EL element according to the Second Embodiment;

FIG. 12 is an enlarged plan view of a side of a central part in another example of the auxiliary electrode in the organic EL element according to the Second Embodiment; and

FIG. 13 is a plan view of a conventional example.

### BEST MODE FOR CARRYING OUT THE INVENTION

### First Embodiment

Hereinafter, an organic EL element according to First Embodiment of the present invention will be described.

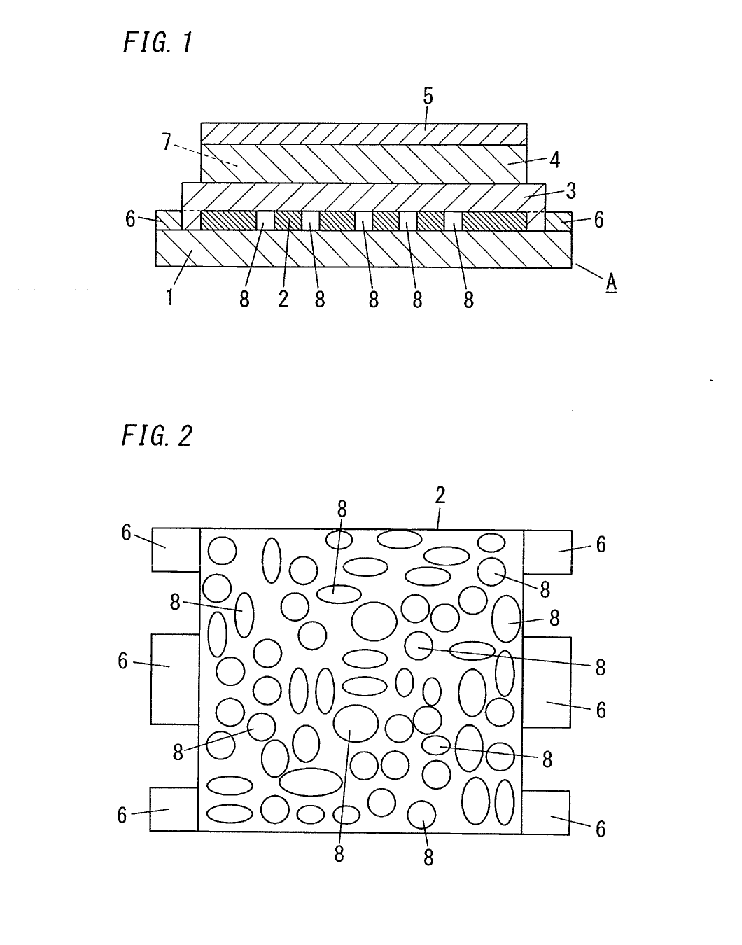

FIG. 1 shows one example of an organic EL element A according to the present embodiment. This organic EL element A is provided as an organic EL panel that is formed into a planar shape. Further, this organic EL element A is provided by laminating an auxiliary electrode 2, a first electrode 3, a functional layer 4 and a second electrode 5 in that order, from a side of a substrate 1.

The substrate 1 is used for supporting of the auxiliary electrode 2, first electrode 3, functional layer 4 and second electrode 5, and the like. It is preferred that the substrate 1 has light transmitting property, and may be colorless or colored. Alternatively, the substrate 1 may be transparent or translucent. Examples of a material for the substrate 1, although not limited to them, include glass such as soda-lime glass and alkali-free glass, and plastic such as polyester, polyolefin, polyamide resin, epoxy resin and fluorine-based resin. The substrate 1 may be formed into a film shape or a plate shape.

The auxiliary electrode 2 is used for supplying electric power to the first electrode 3. The auxiliary electrode 2 is formed of a metal that is a material having electric conductivity higher than the first electrode 3. It is preferred that the auxiliary electrode 2 is formed of MAM (a laminated body of Mo/Al/Mo), APC (a laminated body of Ag/Pd/Cu), or the like. The auxiliary electrode 2 is formed into a rectangle in plan view. However, the shape of auxiliary electrode 2 is not limited to the rectangle. The shape may be a circle or the like. The auxiliary electrode 2 is provided at an outer peripheral edge thereof with power supply terminals 6 that are projected. The power supply terminals 6 are made of the same material as the auxiliary electrode 2, and formed integrally with the auxiliary electrode 2. The auxiliary electrode 2 and power supply terminals 6 are formed on a surface of the substrate 1 by an appropriate method, such as a vacuum deposition method or a sputtering method.

The first electrode 3 is formed as a transparent electrode that has light transmitting property. This first electrode 3 is provided so as to serves as an anode. In this case, the anode is an electrode for injecting holes into the functional layer 4. It is preferred that the first electrode 3 is formed of a metal, an alloy, a conductive compound or a mixture thereof, which has a large work function. In particular, it is preferred that the first electrode 3 is formed of a material having the work function of 4 [eV] or more, namely, the work function of the first electrode 3 is 4 [eV] or more. Concrete examples of the material for the first electrode 3 include metal oxides, such as ITO (Indium-Tin Oxide), SnO₂, ZnO, IZO (Indium-Zinc Oxide) and AZO (Aluminum-added Zinc Oxide), and the like. It is preferred that the first electrode 3 has a light transmittance of 70% or more, and more preferably, 90% or more. In addition, the first electrode 3 has a sheet resistance of several hundred [Ω/□] or less, and more preferably, 100 [Ω/□] or less. A thickness of the first electrode 3 is appropriately set so that characteristics of the light transmittance, the sheet resistance and the like of the first electrode 3 are desired degrees. It is preferred that the thickness of the first electrode 3 is 500 [nm] or less, and more preferably, is within a range of 10 to 200 [nm]. The first electrode 3 is formed by an appropriate method, such as a vacuum deposition method, a sputtering method or an application method.

The functional layer 4 is a layer that is disposed between the first electrode 3 and second electrode 5. The functional layer 4 is configured by one or more layers including a light-emitting layer 7. That is, the functional layer 4 may be configured by a single layer including only the light-emitting layer 7. Alternatively, the functional layer 4 may include layers, such as a hole injection layer, a hole transport layer, an electron injection layer and an electron transport layer as necessary, in addition to the light-emitting layer 7. For example, the functional layer 4 may include the hole injection layer, hole transport layer, light-emitting layer, electron injection layer and electron transport layer, and those layers may be laminated in that order.

In a case where the functional layer 4 includes the hole injection layer, examples of a material for the hole injection layer include: a conductive polymer such as PEDOT/PSS or polyaniline; a conductive polymer that is doped with an arbitrary acceptor or the like; and a material with both of conductive property and light transmitting property, such as carbon nanotube, CuPc (Copper Phthalocyanine), MTDATA[4,4′,4″-Tris(3-methyl-phenylphenylamino)tri-phenylamine], TiOPC (Titanyl Phthalocyanine) or amorphous carbon. The hole injection layer is formed by an appropriate method, such as an application method or a deposition method.

In a case where the functional layer 4 includes the hole transport layer, a material for the hole transport layer (a hole transporting material) is appropriately selected from a group of compounds having hole transporting property. Here, it is preferred that the selected compound has electron donation property and is further stable even when being radical-cationized by electron donation. Examples of the hole transporting material include a triarylamine-based compound, an amine compound containing a carbazole group, an amine compound containing a fluorene derivative, and starburst amines (m-MTDATA). Typical examples of those compounds include polyaniline, 4,4′-bis[N-(naphthyl)-N-phenyl-amino]biphenyl(α-NPD), N,N′-bis(3-methylphenyl)-(1,1′-biphenyl)-4,4′-diamine(TPD), 2-TNATA, 4,4′,4″-tris(N-(3-methylphenyl)N-phenylamino)triphenylamine(MTDATA), 4,4′-N,N′-dicarbazolebiphenyl(CBP), spiro-NPD, spiro-TPD, spiro-TAD and TNS. Examples of TDATA-based materials include 1-TMATA, 2-TNATA, p-PMTDATA and TFATA. However, the hole transporting material is not limited to those, and an arbitrary hole transporting material generally known may be used. The hole transport layer is formed by an appropriate method, such as an application method or a deposition method.

The light-emitting layer 7 is a layer for generating light emission in the functional layer 4. The light-emitting layer 7 is formed of a well-known material that is known as a material for an organic EL element. Concrete examples of the material for the light-emitting layer 7, although not limited to them, include: anthracene; naphthalene; pyrene; tetracene; coronene; perylene; phthaloperylene; naphthaloperylene; diphenylbutadiene; tetraphenylbutadiene; coumalin; oxadiazole; bisbenzoxazoline; bisstyryl; cyclopentadiene; a quinoline-metal complex; a tris(8-hydroxyquinolinate)aluminum complex; a tris(4-methyl-8-quinolinate)aluminum complex; a tris(5-phenyl-8-quinolinate)aluminum complex; an aminoquinoline-metal complex; a benzoquinoline-metal complex; a tri-(p-terphenyl-4-yl)amine; 1-aryl-2,5-di(2-thienyl)pyrrole derivatives; pyrane; quinacridone; rubrene; a distyryl benzene derivative; a distyrylarylene derivative; a distyrylamine derivative; and various phosphor pigments. Two kinds or more of those materials may be combined. In addition to materials that cause fluorescent emission, the following materials may be employed: materials that cause light emission from spin-multiplets (such as phosphorescent light emission); and compounds that have a portion of causing the light emission from the spin-multiplets in a part of a molecule. The light-emitting layer 7 may be formed by a dry-type process such as a deposition method or a transfer method, or by a wet-type process such as an application method.

In a case where the functional layer 4 includes the electron transport layer, it is preferred that a material for the electron transport layer (an electron transporting material) is a compound that is capable of transporting electrons and provides, to the light-emitting layer, an excellent electron injecting effect, depending on receiving injection of electrons from the second electrode 5. In addition, it is preferred that the electron transporting material is a compound that prevents holes from moving to the electron transport layer and has an excellent capability for forming of a thin film. Examples of the electron transporting material include Alq₃, an oxadiazole derivative, starburst oxadiazole, a triazole derivative, a phenyl quinoxaline derivative, and a silole derivative. Concrete examples of the electron transporting material include fluorene, bathophenanthroline, bathocuproine, anthraquinodimethane, diphenoquinone, oxazole, oxadiazole, triazole, imidazole, anthraquinodimethane, 4,4′-N,N′-dicarbazolebiphenyl (CBP), a compound including any of those, a metal-complex compound, and a nitrogen-containing five-membered ring derivative. Concrete examples of the metal-complex compound include tris(8-hydroxyquinolinate)aluminum, tri(2-methyl-8-hydroxyquinolinate)aluminum, tris(8-hydroxyquinolinate)gallium, bis(10-hydroxybenzo[h]quinolinate)beryllium, bis(10-hydroxybenzo[h]quinolinate)zinc, bis(2-methyl-8-quinolinate)(o-cresolate)gallium, bis(2-methyl-8-quinolinate)(1-naphtholato)aluminum, and bis(2-methyl-8-quinolinate)-4-phenylphenolate, although not limited to them. Examples of the nitrogen-containing five-membered ring derivative preferably include oxazole, thiazole, oxadiazole, thiadiazole, and a triazole derivative. Concrete examples of the nitrogen-containing five-membered ring derivative include 2,5-bis(1-phenyl)-1,3,4-oxazole, 2,5-bis(1-phenyl)-1,3,4-thiazole, 2,5-bis(1-phenyl)-1,3,4-oxadiazole, 2-(4′-tert-butylphenyl)-5-(4″-biphenyl)1,3,4-oxadiazole, 2,5-bis(1-naphthyl)-1,3,4-oxadiazole, 1,4-bis[2-(5-phenylthiadiazolyl)]benzene, 2,5-bis(1-naphthyl)-1,3,4-triazole, and 3-(4-biphenylyl)-4-phenyl-5-(4-t-butylphenyl)-1,2,4-triazole, although not limited to them. In addition, the examples of the electron transporting material also include a polymer material that is used for an organic EL element. Examples of the polymer material include polyparaphenylene, a polyparaphenylene derivative, fluorene, and a fluorene derivative. The electron transport layer is formed by an appropriate method, such as an application method or a deposition method. A thickness of the electron transport layer is preferably set in a range of 10 to 300 [nm] for example, although in particular not limited to it.

In a case where the functional layer 4 includes the electron injection layer, examples of a material for the electron injection layer include an alkali metal, an alkali metal halide, an alkali metal oxide, an alkali metal carbonate, an alkali earth metal, and an alloy including those metals. Concrete examples of the material for the electron injection layer include Na, a NaK alloy, Li, LiF, Li₂O, Li₂CO₃, Mg, MgO, a magnesium-indium mixture, an aluminum-lithium alloy, and an Al/LiF mixture. The electron injection layer may be formed as an organic layer doped with an alkali metal such as Li, Na or Cs, or an alkali earth metal such as Ca. The electron injection layer is formed by an appropriate method such as a deposition method.

The second electrode 5 is provided so as to serves as a cathode. In this case, the cathode is an electrode for injecting electrons into the light-emitting layer 7. It is preferred that the second electrode 5 is formed of a metal, an alloy, a conductive compound or a mixture thereof, which has a small work function. In particular, it is preferred that the second electrode 5 is formed of a material having the work function of 5 [eV] or less, namely, the work function of the second electrode 5 is 5 [eV] or less. Examples of the material for this second electrode 5 include Al, Ag, and MgAg. Further, the second electrode 5 may be formed of an Al/Al₂O₃ mixture or the like. In a case where the second electrode 5 is provided so as to transmit light emitted from the light-emitting layer 7, it is preferred that the second electrode 5 includes layers, and a part of the layers is formed of a transparent conductive material, such as ITO or IZO. In a case where the first electrode 3 is provided so as to transmit light emitted from the light-emitting layer 7, it is preferred that a light transmittance of the second electrode 5 is 10% or less. On the other hand, in the case where the second electrode 5 is provided so as to transmit light emitted from the light-emitting layer 7, it is preferred that the light transmittance of the second electrode 5 is 70% or more. A thickness of the second electrode 5 is appropriately set so that characteristics of the light transmittance, the sheet resistance and the like of the second electrode 5 are desired degrees. Although depending on the material for the second electrode 5, it is preferred that the thickness of the second electrode 5 is 500 [nm] or less, and more preferably, is within a range of 20 to 200 [nm]. The second electrode 5 is formed by an appropriate method, such as a vacuum deposition method or a sputtering method.

In the organic EL element A shown in FIG. 2, the light-emitting layer 7 is disposed between the first electrode 3 and second electrode 5. As at least one of the first and second electrodes 3 and 5, the first electrode 3 is provided as a transparent electrode that has the light transmitting property. Further, the auxiliary electrode 2 is provided on an opposite side of the first electrode 3 from a side of the light-emitting layer 7 (that is, on a surface of the first electrode facing a side of the substrate 1). A surface and of an outer peripheral edge face of the auxiliary electrode 2 are covered by the first electrode 3. The power supply terminals 6 projected from the auxiliary electrode 2 are provided so as to reach an outer peripheral edge of the substrate 1 while passing through the outer peripheral edge face of the first electrode 3.

In the organic EL element A described above, the electric power is supplied to the auxiliary electrode 2 through the power supply terminals 6 and is further supplied from the auxiliary electrode 2 to the first electrode 3 to apply a voltage between the first electrode 3 and second electrode 5. Accordingly, current flows from the first electrode 3 to the second electrode 5 through the functional layer 4, and therefore the light-emitting layer 7 in the functional layer 4 emits light. The light emitted from the light-emitting layer 7 is taken out to the outside through the first electrode 3, a plurality of holes 8 that are provided in the auxiliary electrode 2, and the substrate 1.

FIG. 2 shows one example of the auxiliary electrode 2. The auxiliary electrode 2 is provided with the plurality of holes 8. As shown in FIG. 1, each of the plurality of holes 8 is formed so as to penetrate the auxiliary electrode along a thickness direction (that agrees with a direction in which each layer is laminated on the substrate 1). Here, in plan view, the plurality of holes 8 according to the present embodiment have not the same shapes, but at least two kinds of geometrical shapes, such as a circle and an ellipse. A size of each hole 8 is not limited in particular. For example, in a case where a hole 8 has a circle shape, a diameter size thereof may be in a range of 0.2 to 3.0 [cm]. In a case where a hole 8 has an ellipse shape, a major axis size thereof may be in a range of 0.5 to 5.0 [cm], and a minor axis size thereof may be in a range of 0.2 to 3.0 [cm]. In plan view of the auxiliary electrode 2, positions of the plurality of holes 8 are also not limited in particular, and may be randomly arranged. The plurality of holes 8 may be provided as voids, or be filled with the material for the first electrode 3.

According to the above-mentioned organic EL element A provided using the auxiliary electrode 2 shown in FIG. 2, the plurality of holes 8 are non-uniformly and randomly formed in the auxiliary electrode 2 without the auxiliary electrode 2 being formed into a grid shape, and accordingly, even when a view angle is deep, namely, even when the organic EL element is viewed from an inclination angle closer to the horizontal level, it is possible to avoid occurrence of a situation where grids of an auxiliary electrode overlap each other. Accordingly, the light emission luminance is hardly reduced. In addition, because the plurality of holes 8 are non-uniformly and randomly formed in the auxiliary electrode 2, it is possible to prevent the light, emitted from the light-emitting layer 7, from being diffracted by the auxiliary electrode 2, and accordingly, reduce change of light emission color of the organic EL element A. Furthermore, by changing the sizes, shapes or positions of the plurality of holes 8, it is possible to design the auxiliary electrode 2 having an opening structure according to an ideal distribution of the sheet resistance. Therefore, it is possible to easily uniformize current density of the first electrode (transparent electrode) 3 depending on the power supply from the auxiliary electrode 2, and easily enhance uniformity of the light emission luminance of the organic EL element A.

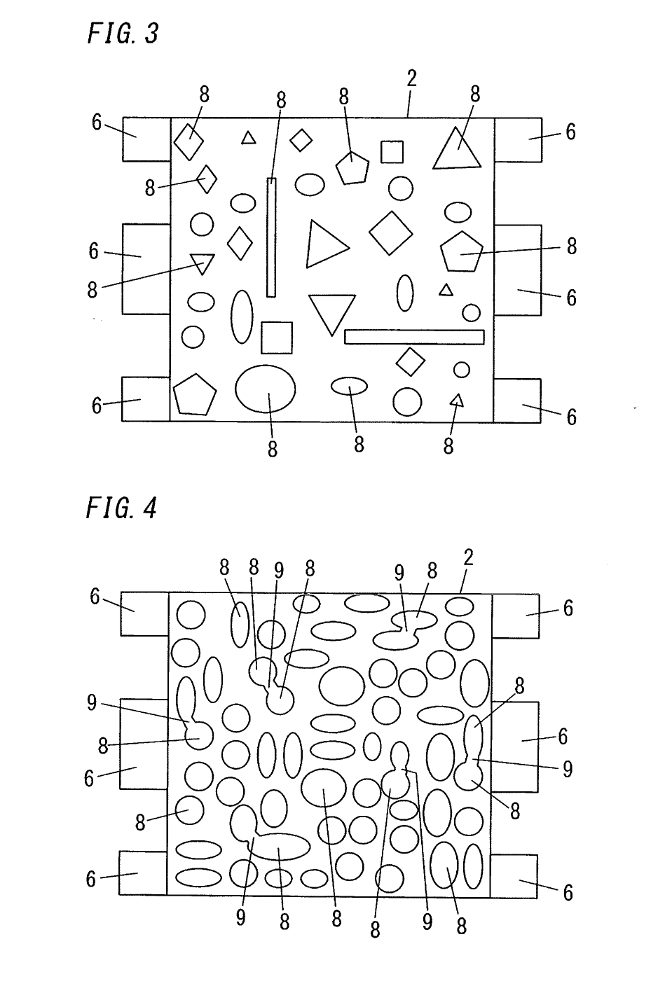

FIG. 3 shows another example of the auxiliary electrode 2. This auxiliary electrode 2 is provided with a plurality of holes 8 that have polygonal shapes, such as a triangle, a quadrangle and a pentagon, in plan view. Some of the plurality of holes 8 may have a polygonal shape that is more than a pentagon. Sizes and positions of the plurality of holes 8 are not limited in particular. In addition to the plurality of holes 8 having the polygonal shapes, the auxiliary electrode 2 may be provided with holes 8 having circles and ellipses.

In the case of the auxiliary electrode 2 shown in FIG. 3, in addition to the same effect as in that shown in FIG. 2, it is possible to more easily design the auxiliary electrode 2 having the opening structure according to the ideal distribution of the sheet resistance, through more diversification of the shapes of the plurality of holes 8 in plan view, compared with that shown in FIG. 2. Therefore, it is possible to more easily uniformize the current density of the first electrode (transparent electrode) 3 and more easily enhance uniformity of the light emission luminance of the organic EL element A.

FIG. 4 shows yet another example of the auxiliary electrode 2. This auxiliary electrode 2 is provided with coupling-holes 9, each of which is provided to couple two holes 8 that are mutually adjacent in plan view. That is, the auxiliary electrode 2 in this drawing is formed by coupling, with a coupling-hole 9, two holes 8 and 8 mutually adjacent in plan view shown in FIG. 2. Similarly to the plurality of holes 8, each of the coupling-holes 9 is formed as a notch that penetrates the auxiliary electrode 2 along the thickness direction. A shape of the coupling-hole 9 in plan view is arbitrary as long as two holes 8 and 8 mutually adjacent are communicated with each other by the coupling-hole 9. For example, the shape may be formed into a polygonal shape such as a circle, an ellipse, a linear shape or a quadrangle. Further, three or more holes 8 may be mutually coupled by a single coupling-hole 9. Other structures are similar to those in FIG. 2.

In the case of the auxiliary electrode 2 shown in FIG. 4, in addition to the same effect as in that shown in FIG. 2, it is possible more easily design the auxiliary electrode 2 having the opening structure according to the ideal distribution of the sheet resistance, through diversification such that the plurality of holes 8 have more distorted shapes in plan view, compared with that shown in FIG. 2. Therefore, it is possible to more easily uniformize the current density of the first electrode (transparent electrode) 3 and more easily enhance uniformity of the light emission luminance of the organic EL element A.

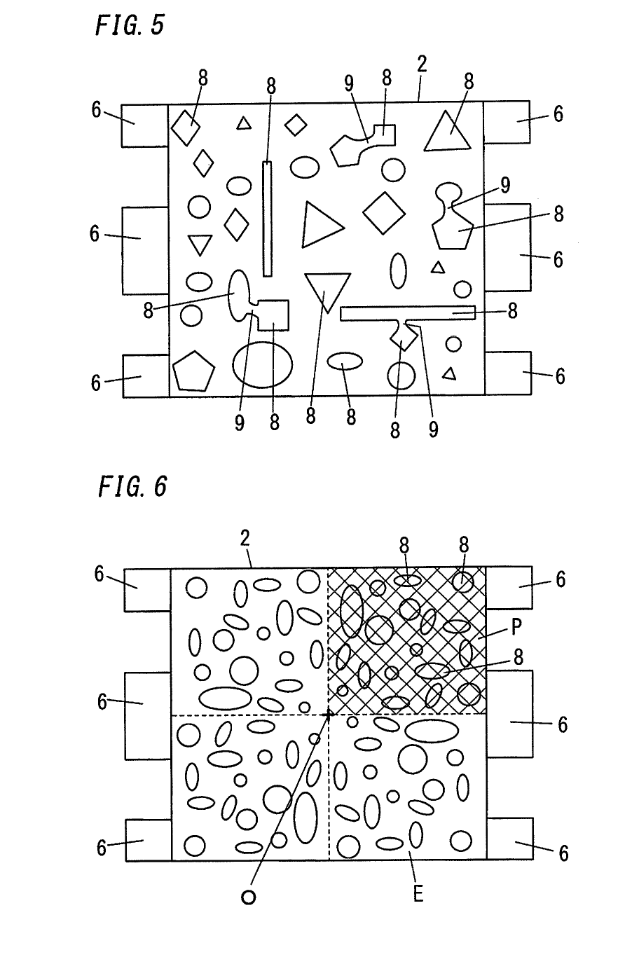

FIG. 5 shows yet another example of the auxiliary electrode 2. This auxiliary electrode 2 is provided with coupling-holes 9, each of which is provided to couple two holes 8 and 8 mutually adjacent in plan view shown in FIG. 3. In this case, two holes 8 and 8 having polygonal shapes in plan view are mutually coupled by a coupling-hole 9. Further, a hole 8 having a circle or an ellipse and a hole 8 having a polygonal shape in plan view are mutually coupled by a coupling-hole 9. Other structures are similar to those in FIGS. 3 and 4. The auxiliary electrode 2 in FIG. 5 can provide the same effect as that in FIG. 4.

In the above-mentioned auxiliary electrodes 2 as shown in FIGS. 2 to 5, it is preferred that the plurality of holes 8 in an emission region E of the organic EL element A are arranged so as to have four-hold rotational symmetry around a rotational axis that is at a center O of the emission region E. For example, at part of the auxiliary electrodes 2 in FIG. 6, a patterned-holes unit P (shown with hatched lines in FIG. 6) is formed. The plurality of holes 8 are arranged through four-hold rotational symmetry of the patterned-holes unit P around the rotational axis at the center O of the emission region E. Here, the emission region E corresponds to the entire of a surface of the auxiliary electrodes 2 in plan view. A region of the patterned-holes unit P corresponds to one region obtained by quadrisecting the emission region E with two lines passing through the center O.

According to the auxiliary electrode 2 as shown in FIG. 6, it is possible to design the whole of positions of the plurality of holes 8 in the auxiliary electrodes 2 by designing only a part of the positions. Therefore, it is possible to easily form the auxiliary electrode 2.

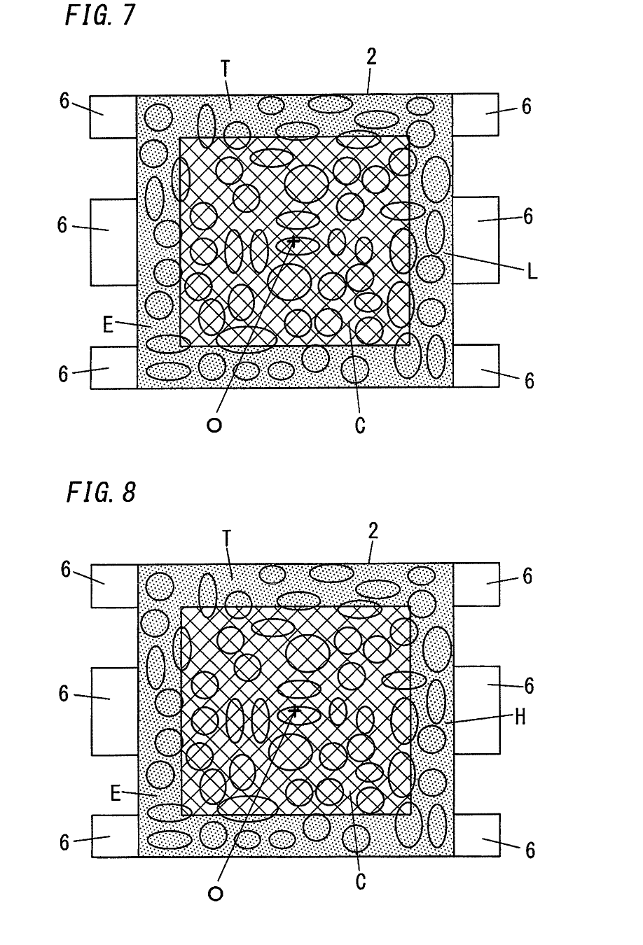

It is preferred that each of the above-mentioned auxiliary electrodes 2 as shown in FIGS. 2 to 6 has a low-opening-rate region L at a peripheral part T of the emission region E of the light-emitting layer 7. In this case, an opening area of holes 8 in the low-opening-rate region L is lower than an opening area of holes 8 in a region corresponding to a central part C of the emission region E. Here, in plan view of the organic EL element A, the emission region E of the light-emitting layer 7 agrees with a region in which the first electrode 3, light-emitting layer 7 and second electrode 5 overlap mutually (that is, a region of the light-emitting layer 7 sandwiched between the first electrode 3 and second electrode 5). The light-emitting layer 7 emits light through this region by receiving power supply. For example, as shown in FIG. 7, in plan view, the emission region E is provided so as to correspond to the entire of a surface of the auxiliary electrodes 2. The above-mentioned peripheral part T is a region that is provided to have a prescribed width size along an outer edge of the emission region E (shown with dots in FIG. 7). The above-mentioned central part C is a region other than the peripheral part T of the emission region E (shown with hatched lines in FIG. 7). Regarding the emission region E, a ratio of the peripheral part T to the central part C may be appropriately set depending on a type or size of the organic EL element A, a material therefor, or the like. For example, the central part C of the emission region E may be set to hold 70 to 95% of the whole area of the emission region E around the center O of the emission region E, and the remaining region may be set as the peripheral part T.

The low-opening-rate region L is provided at a region corresponding to the peripheral part T of the emission region E of the auxiliary electrode 2. The opening area of holes 8 in the low-opening-rate region L is lower than that in a region corresponding to the central part C of the emission region E of the auxiliary electrode 2. The low-opening-rate region L may be the entire region corresponding to the peripheral part T, or part of the region. The low-opening-rate region L means that the total of opening areas of all holes 8 in the region is less than that in the region corresponding to the central part C. It is preferred that an opening rate of holes 8 in the low-opening-rate region L is lower than that in the region corresponding to the central part C by 5% or more. Here, the opening rate of holes 8 in the low-opening-rate region L is defined by a formula of ((the total of opening areas of all holes 8 in the low-opening-rate region L)/(the whole area of the low-opening-rate region L also including the opening areas of the holes 8)×100). The opening rate of holes 8 in the region corresponding to the central part C is defined by a formula of ((the total of opening areas of all holes 8 in the region corresponding to the central part C)/(the whole area of the region corresponding to the central part C also including the opening areas of the holes 8)×100). A difference between the opening rate of holes 8 in the low-opening-rate region L and the opening rate of holes 8 in the region corresponding to the central part C may be appropriately set depending on a type or size of the organic EL element A, a material therefor, or the like. It is preferred that the opening rate of holes 8 in the low-opening-rate region L is lower than that in the region corresponding to the central part C by 10% or less, although not limited to such a rate. Sizes or density of holes 8 in the low-opening-rate region L may be less than that in the region corresponding to the central part C.

In this way, the auxiliary electrode 2 has the low-opening-rate region L at the peripheral part T of the emission region E of the light-emitting layer 7 and the opening area of holes 8 in the low-opening-rate region L is lower than that in the region corresponding to the central part C of the emission region E. Accordingly, in the emission region E of the light-emitting layer 7, it is possible to increase current density of the peripheral part T to be more than that of the central part C. Therefore, it is possible to more easily enhance uniformity of the light emission luminance in the emission region E of the light-emitting layer 7 of the organic EL element A.

Here, the auxiliary electrode 2 is provided at the outer peripheral edge thereof with the power supply terminals 6 for power supply. In this case, it is preferred that the low-opening-rate region L is disposed at positions close to the power supply terminals 6. Here, “a position close to the power supply terminal 6” means a position in a range from a position of the power supply terminal to about 1 [cm] or less. In this case, it is possible to increase current density of the regions corresponding to the positions close to the power supply terminals 6 to be more than that of the central part C, in the emission region E of the light-emitting layer 7. Therefore, it is possible to more easily enhance uniformity of the light emission luminance in the emission region E of the light-emitting layer 7 of the organic EL element A.

It is preferred that each of the above-mentioned auxiliary electrodes 2 as shown in FIGS. 2 to 6 has a high-opening-rate region H at the peripheral part T of the emission region E of the light-emitting layer 7. In this case, the opening area of holes 8 in the high-opening-rate region H is higher than the opening area of holes 8 in the region corresponding to the central part C of the emission region E. Here, the emission region E, peripheral part T and central part C of the light-emitting layer 7 are defined similarly to the above descriptions. For example, as shown in FIG. 8, in plan view, the emission region E is provided so as to correspond to the entire of the surface of the auxiliary electrodes 2. The above-mentioned peripheral part T is a region that is provided to have a prescribed width size along the outer edge of the emission region E (shown with dots in FIG. 8). The above-mentioned central part C is a region other than the peripheral part T of the emission region E (shown with hatched lines in FIG. 8). In addition, regarding the emission region E, the ratio of the peripheral part T to the central part C is also defined similarly to the above descriptions.

The high-opening-rate region H is provided at a region corresponding to the peripheral part T of the emission region E of the auxiliary electrode 2. The opening area of holes 8 of the high-opening-rate region H is higher than that in a region corresponding to the central part C of the emission region E of the auxiliary electrode 2. The high-opening-rate region H may be the entire region corresponding to the peripheral part T, or part of the region. The high-opening-rate region H means that the total of opening areas of all holes 8 in the region is more than that in the region corresponding to the central part C. It is preferred that an opening rate of holes 8 in the high-opening-rate region H is higher than that in the region corresponding to the central part C by 5% or more. Here, the opening rate of holes 8 in the high-opening-rate region H is defined by a formula of ((the total of opening areas of all holes 8 in the high-opening-rate region H)/(the whole area of the high-opening-rate region H also including the opening areas of the holes 8)×100). The opening rate of holes 8 in the region corresponding to the central part C is defined by a formula of ((the total of opening areas of all holes 8 in the region corresponding to the central part C)/(the whole area of the region corresponding to the central part C also including the opening areas of the holes 8)×100). A difference between the opening rate of holes 8 in the high-opening-rate region H and the opening rate of holes 8 in the region corresponding to the central part C may be appropriately set depending on a type or size of the organic EL element A, a material therefor, or the like. It is preferred that the opening rate of holes 8 in the high-opening-rate region H is higher than that in the region corresponding to the central part C by 10% or less, although not limited to such a rate. Sizes or density of holes 8 in the high-opening-rate region H may be more than that in the region corresponding to the central part C.

In this way, the auxiliary electrode 2 has the high-opening-rate region H at the peripheral part T of the emission region E of the light-emitting layer 7 and the opening area of holes 8 in the high-opening-rate region H is higher than that in the region corresponding to the central part C of the emission region E. Accordingly, in light emission from the emission region E of the light-emitting layer 7, light emitted from the region corresponding to the peripheral part T is taken out to the outside more than light emitted from the region corresponding to the central part C. Accordingly, in the light-emitting layer 7, even when the light emission amount of the central part C is actually more than that of the peripheral part T, it is possible to increase the amount of light taken out from the peripheral part T to be more than that from the central part C. Therefore, it is possible to more easily enhance uniformity of the light emission luminance in the emission region E of the light-emitting layer 7 of the organic EL element A. Here, the auxiliary electrode 2 is provided at the outer peripheral edge thereof with the power supply terminals 6 for power supply. In this case, it is preferred that the high-opening-rate region H is disposed at positions close to the power supply terminals 6. Here, the definition of “a position close to the power supply terminal 6” is the same as the definition already described. In this case, it is possible to more easily take out light from the regions corresponding to the positions close to the power supply terminals 6 of the auxiliary electrode 2, compared with from the region corresponding to the central part C, in the emission region E of the light-emitting layer 7. Therefore, it is possible to more easily enhance uniformity of the light emission luminance in the emission region E of the light-emitting layer 7 of the organic EL element A.

### Second Embodiment

Hereinafter, an organic EL element according to Second Embodiment of the present invention will be described.

In the organic EL element A according to the First Embodiment, the plurality of holes 8 are randomly arranged in the auxiliary electrode 2. On the other hand, an organic EL element A according to the present embodiment is characterized in that a plurality of holes 8 are uniformly arranged in an auxiliary electrode 12. Components similar to the First Embodiment are assigned with same reference numerals, and explanations thereof will be appropriately omitted.

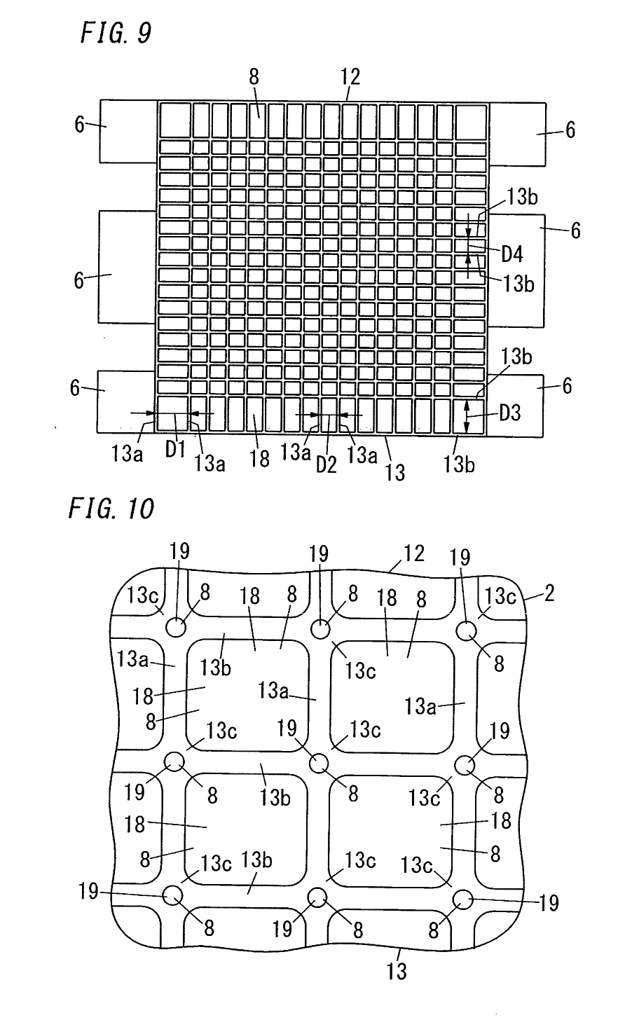

As shown in FIG. 9, the auxiliary electrode 12 according to the present embodiment includes a grid electrode 13 that is formed into a grid-shape by arranging a plurality of elongated members so as to cross mutually at right angles. Specifically, the plurality of elongated members include: a plurality of first elongated grid members 13a that extend in a first direction (a vertical direction in FIG. 9); and a plurality of second elongated grid members 13b that extend in a second direction (a lateral direction in FIG. 9) forming a right angle with the first direction. The grid electrode 13 is formed by the plurality of first elongated grid members 13a and the plurality of second elongated grid members 13b being integrally arranged so as to cross mutually in a form of mesh. Accordingly, the auxiliary electrode 12 includes a plurality of openings 18 that are uniformly formed by being surrounded by the plurality of first elongated grid members 13a and the plurality of second elongated grid members 13b. Each of the plurality of openings 18 is formed into an approximately rectangle in plan view so as to penetrate the auxiliary electrode along the thickness direction. The plurality of openings 18 are equivalent to the plurality of holes 8 according to the present embodiment.

All of the plurality of first elongated grid members 13a according to the present embodiment are not uniformly arranged at regular intervals in the second direction, but some of the members 13a are arranged at different intervals. Specifically, as shown in FIG. 9, in the second direction, a distance D1 between two adjacent first elongated grid members 13a arranged on an end side of an emission region E is set to be more than a distance D2 between two adjacent first elongated grid members 13a arranged near a central part of the emission region E.

Similarly, all of the plurality of second elongated grid members 13b are not uniformly arranged at regular intervals in the first direction, but some of the members 13b are arranged at different intervals. Specifically, as shown in FIG. 9, in the first direction, a distance D3 between two adjacent second elongated grid members 13b arranged on an end side of the emission region E is set to be more than a distance D4 between two adjacent second elongated grid members 13b arranged near a central part of the emission region E.

In addition, the distance D1 between the two adjacent first elongated grid members 13a is set to be different from the distance D3 between the two adjacent second elongated grid members 13b. The distance D2 between the two adjacent first elongated grid members 13a is set to be different from the distance D4 between the two adjacent second elongated grid members 13b.

The plurality of first elongated grid members 13a and the plurality of second elongated grid members 13b are arranged at the distances D1 to D4 as described above, and accordingly, the grid electrode 13 is provided with the plurality of holes 8 (the plurality of openings 18) having two kinds or more of geometrical shapes (two kinds or more of rectangles) in plan view.

The distances D1 to D4 are not limited to settings as described above. For example, while the distance D1 is set to be different from the distance D3, the distance D2 may be set to be equal to the distance D4. In this case, openings 18 near the central part of the emission region E have squares, and openings 18 on the side of the peripheral part of the emission region E have rectangles.

As shown in FIG. 10, the grid electrode 13 according to the present embodiment may include, in addition to the above-mentioned plurality of openings 18, a plurality of through-holes 19 that are formed into circles in plan view for example. The plurality of through-holes 19 are respectively formed in crossing parts 13c, at which the first elongated grid members 13a and second elongated grid members 13b cross mutually, so as to penetrate the crossing parts 13c along the thickness direction.

As described above, the organic EL element A according to the present embodiment includes the above-mentioned grid electrode 13 as the auxiliary electrode 12. Accordingly, it is possible to easily uniformize current density of a first electrode 3 depending on the power supply from the grid electrode 13, and easily enhance uniformity of the light emission luminance of the organic EL element A. Therefore, it is possible to drive the organic EL element A at a lower voltage, and further improve the emission efficiency. In particular, the plurality of holes 8 according to the present embodiment include the plurality of through-holes 19 in addition to the plurality of openings 18. Accordingly, it is possible to more enhance the light emission luminance near the crossing parts 13c.

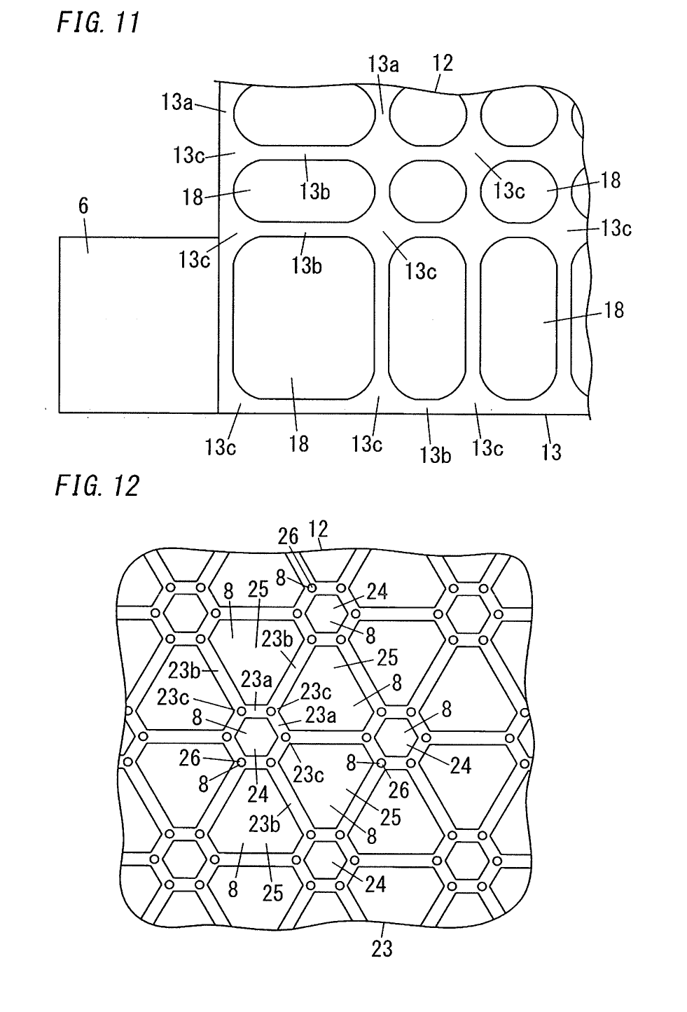

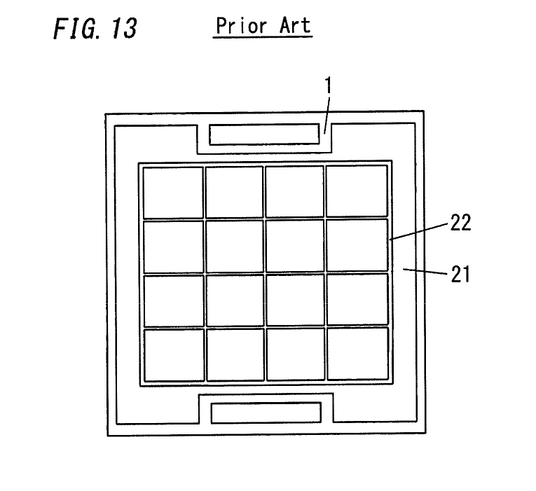

Incidentally, the plurality of openings 18 according to the present embodiment are formed into polygonal shapes in plan view (rectangles in FIG. 9), and further, as shown in FIG. 10, corners of each opening 18 are formed into round shapes in plan view. Here, regarding the plurality of openings 18 according to the present embodiment, the round-shaped corners may be formed so as to have different curvature radiuses, depending on positions of the openings 18. Specifically, as shown in FIG. 11, regarding openings 18 that are disposed on the side of the peripheral part of the emission region E, curvature radiuses of round-shaped corners thereof may be set to be larger than curvature radiuses of round-shaped corners of openings 18 that are disposed near the central part of the emission region E shown in FIG. 10. The curvature radiuses of the corners of the openings 18 are set as described above, thereby enhancing the light emission luminance near the central part of the emission region E. Accordingly, it is possible to more easily enhance uniformity of the light emission luminance. Therefore, it is possible to drive the organic EL element A at a lower voltage, and further improve the emission efficiency.

Hereinafter, another example of the auxiliary electrode 12 according to the present embodiment will be described. The auxiliary electrode 12 already described above, as shown in FIGS. 9 to 11, includes the grid electrode 13 that is formed by arranging the plurality of elongated members (the first elongated grid members 13a and second elongated grid members 13b) so as to cross mutually at right angles. On the other hand, another example of the auxiliary electrode 12, as shown in FIG. 12, includes a grid electrode 23 that is formed into a grid-shape by arranging a plurality of elongated members so as to be joined mutually by prescribed angles. In this case, the plurality of elongated members include a plurality of short-piece members 23a and a plurality of long-piece members 23b. Specifically, six short-piece members 23a are coupled and arranged so as to respectively correspond to six sides of one regular hexagon. That is, in one regular hexagon, two adjacent short-piece members 23a are arranged so as to be joined by 120 degrees. Further, six long-piece members 23b are coupled and arranged so as to extend from six joining parts 23c (six apexes) of the regular hexagon in question to the outside. Further, an end of each of the six long-piece members 23b is coupled to a joining part 23c (an apex) of another regular hexagon that is formed by six short-piece members 23a. In other words, two short-piece members 23a and one long-piece member 23b are arranged to one joining part 23c so as to be joined mutually by 120 degrees.

As a result, the auxiliary electrode 12 is provided with a plurality of openings 24 and a plurality of openings 25 that are uniformly formed by being surrounded by the plurality of short-piece members 23a and the plurality of long-piece members 23b. Each of the plurality of openings 24 is formed into a regular hexagon in plan view so as to penetrate the auxiliary electrode along the thickness direction. Each of the plurality of openings 25 is formed into an approximately regular triangle in plan view so as to penetrate the auxiliary electrode along the thickness direction. The plurality of openings 24 and plurality of openings 25 are equivalent to the plurality of holes 8 according to the present embodiment. As shown in FIG. 12, precisely, each opening 25 having the approximately regular triangle has an opening structure such that three apexes of a regular triangle are cut off.

Further, as shown in FIG. 12, the grid electrode 23 includes a plurality of through-holes 26, in addition to the plurality of openings 24 and plurality of openings 25 as the plurality of holes 8. Each through-hole 26 is formed into, for example, a circle shape in plan view. The plurality of through-holes 26 are respectively formed in the joining parts 23c, to each of which two short-piece members 23a and one long-piece member 23b are joined mutually, so as to penetrate the joining parts 23c along the thickness direction.

The organic EL element A according to the present embodiment includes the above-mentioned grid electrode 23 as another example of the auxiliary electrode 12, and accordingly, it is possible to easily uniformize current density of a first electrode 3 depending on the power supply from the grid electrode 23, and easily enhance uniformity of the light emission luminance of the organic EL element A.

Corners of the openings 24 and 25 of the grid electrode 23 may be formed into round shapes in plan view (not shown). In this case, the round-shaped corners of the grid electrode 23 may be formed so as to have different curvature radiuses depending on positions of the openings 24 and 25, similarly to the grid electrode 13. Specifically, regarding openings 24 and 25 that are disposed on the side of the peripheral part of the emission region E, curvature radiuses of round-shaped corners thereof may be set to be larger than curvature radiuses of round-shaped corners of openings 24 and 25 that are disposed near the central part of the emission region E.

Although the present invention has been described with reference to certain preferred embodiments, numerous modifications and variations can be made by those skilled in the art without departing from the true spirit and scope of this invention, namely claims.

1-15. (canceled)

16. An organic electroluminescent element, comprising:
a light-emitting layer disposed between electrodes,
at least one of the electrodes being a transparent electrode that has light transmitting property; and
an auxiliary electrode disposed on an opposite side of the transparent electrode from a side of the light-emitting layer, the auxiliary electrode being formed of a metal,
the auxiliary electrode being provided with a plurality of holes that have at least two kinds of geometrical shapes in plan view.

17. The organic electroluminescent element according to claim 16,
wherein the auxiliary electrode comprises a grid electrode that is formed into a grid-shape by arranging a plurality of elongated members so as to cross mutually, or so as to be joined mutually by prescribed angles, and
wherein the plurality of holes include a plurality of openings that are formed by being surrounded by the plurality of elongated members.

18. The organic electroluminescent element according to claim 17,
wherein the plurality of openings have polygonal shapes in plan view, corners of each opening having round shapes in plan view, and
wherein an opening among the plurality of openings is disposed on a side of a peripheral part of an emission region of the light-emitting layer, a curvature radius of a corner of the opening being set to be larger than a curvature radius of a corner of an opening disposed on a side of a central part of the emission region.

19. The organic electroluminescent element according to claim 17,
wherein the plurality of holes include a through-hole in addition to the plurality of openings, the through-hole being formed in a crossing part at which the plurality of elongated members cross mutually.

20. The organic electroluminescent element according to claim 17,
wherein the plurality of holes include a through-hole in addition to the plurality of openings, the through-hole being formed in a joining part at which the plurality of elongated members are joined mutually by the prescribed angles.

21. The organic electroluminescent element according to claim 16, wherein the plurality of holes include at least one hole that has a circle or an ellipse in plan view.

22. The organic electroluminescent element according to claim 16, wherein the plurality of holes include at least one hole that has a polygonal shape in plan view.

23. The organic electroluminescent element according to claim 16, wherein the plurality of holes include a coupling-hole for coupling holes that are mutually adjacent in plan view.

24. The organic electroluminescent element according to claim 16, wherein the plurality of holes are arranged so as to have four-hold rotational symmetry around a rotational axis that is at a center of the emission region of the light-emitting layer.

25. The organic electroluminescent element according to claim 16,
wherein the auxiliary electrode has a low-opening-rate region at the peripheral part of the emission region of the light-emitting layer, and
wherein, among the plurality of holes, an opening area of holes in the low-opening-rate region is smaller than an opening area of holes in a region corresponding to the central part of the emission region.

26. The organic electroluminescent element according to claim 16,
wherein the auxiliary electrode has a high-opening-rate region at the peripheral part of the emission region of the light-emitting layer, and
wherein, among the plurality of holes, an opening area of holes in the high-opening-rate region is larger than an opening area of holes in a region corresponding to the central part of the emission region.

27. The organic electroluminescent element according to claim 25,
wherein the auxiliary electrode is provided at an outer peripheral edge thereof with a power supply terminal for power supply, and
wherein the low-opening-rate region is disposed at a position close to the power supply terminal.

28. The organic electroluminescent element according to claim 26,
wherein the auxiliary electrode is provided at an outer peripheral edge thereof with a power supply terminal for power supply, and
wherein the high-opening-rate region is disposed at a position close to the power supply terminal.

29. The organic electroluminescent element according to claim 25, wherein an opening rate of the low-opening-rate region is lower than an opening rate of the region corresponding to the central part by at least 5% or more.

30. The organic electroluminescent element according to claim 26, wherein an opening rate of the high-opening-rate region is higher than an opening rate of the region corresponding to the central part by at least 5% or more.

31. The organic electroluminescent element according to claim 18,
wherein the plurality of holes include a through-hole in addition to the plurality of openings, the through-hole being formed in a crossing part at which the plurality of elongated members cross mutually.

32. The organic electroluminescent element according to claim 18,
wherein the plurality of holes include a through-hole in addition to the plurality of openings, the through-hole being fowled in a joining part at which the plurality of elongated members are joined mutually by the prescribed angles.

33. The organic electroluminescent element according to claim 27, wherein an opening rate of the low-opening-rate region is lower than an opening rate of the region corresponding to the central part by at least 5% or more.

34. The organic electroluminescent element according to claim 28, wherein an opening rate of the high-opening-rate region is higher than an opening rate of the region corresponding to the central part by at least 5% or more.
